(19) United States
(12) Patent Application Publication
(10) Pub. No.: US 2009/0120487 A1
(43) Pub. Date: May 14, 2009

(54) Method and System for Assembling A Solar Cell Using a Plurality of Photovoltaic Regions

(75) Inventor: Alelie Funcell, Milpitas, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Solaria Corporation, Fremont, CA (US)

(21) Appl. No.: 12/167,198

(22) Filed: Jul. 2, 2008

Related U.S. Application Data
(63) Continuation of application No. 11/402,490, filed on Apr. 11, 2006.
(60) Provisional application No. 60/716,411, filed on Sep. 12, 2005.

(51) Int. Cl. H01L 31/052; H01L 31/00

(52) U.S. Cl. 136/246; 136/259

(57) ABSTRACT

A solar cell device. The device has a housing member. The device also has a lead frame member coupled to the housing member. In a preferred embodiment, the lead frame member has at least one photovoltaic strip thereon, which has a surface region and a back side region. The device has an optical elastomer material having a first thickness overlying the surface region of the photovoltaic surface. The device has a second substrate member comprising at least one optical concentrating element thereon. The optical concentrating element has a first side and a second side. The device has a first interface within a vicinity of the surface region and the first thickness of the optical elastomer material and a second interface within a vicinity of the second side and the optical elastomer material. In a specific embodiment, the optical concentrating element is coupled to the surface region of the photovoltaic strip such that the optical elastomer material is in between the surface region of the photovoltaic strip and the second side of the optical concentrating element. In a specific embodiment, the device has a spacing comprising essentially the optical elastomer material between the second side of the optical concentrating element and the surface region of the photovoltaic strip. The device has a plurality of particles having a predetermined dimension (e.g., non-compressible and substantially non-deformable particles) spatially disposed overlying the surface region of the photovoltaic strip and within a second thickness of the optical elastomer material to define the spacing between the surface region and the second side of the optical concentrating element. In a specific embodiment, the first interface is substantially free from one or more gaps (e.g., air gaps and/or pockets) and the second interface substantially free from one or more gaps to form a substantially continuous optical interface from the first side of the optical concentrating element, through the first interface, and through the second interface to the photovoltaic strip.

### CROSS-REFERENCES TO RELATED APPLICATIONS

This application is a continuation of U.S. patent application Ser. No. 11/402,490 filed Apr. 11, 2006, which claims priority to U.S. Provisional Application No. 60/716,411 filed Sep. 12, 2005, commonly assigned, and hereby incorporated by reference here.

### BACKGROUND OF THE INVENTION

The present invention relates generally to solar energy techniques. In particular, the present invention provides a method and resulting device fabricated from a plurality of photovoltaic regions provided within one or more substrate members. More particularly, the present invention provides a method and resulting device for manufacturing the photovoltaic regions within the substrate member, which is coupled to a plurality of concentrating elements, using a coupling technique between the photovoltaic regions and respective concentrating elements. Merely by way of example, the invention has been applied to solar panels, commonly termed modules, but it would be recognized that the invention has a much broader range of applicability.

As the population of the world increases, industrial expansion has lead to an equally large consumption of energy. Energy often comes from fossil fuels, including coal and oil, hydroelectric plants, nuclear sources, and others. As merely an example, the International Energy Agency projects further increases in oil consumption, with developing nations such as China and India accounting for most of the increase. Almost every element of our daily lives depends, in part, on oil, which is becoming increasingly scarce. As time further progresses, an era of “cheap” and plentiful oil is coming to an end. Accordingly, other and alternative sources of energy have been developed.

Concurrent with oil, we have also relied upon other very useful sources of energy such as hydroelectric, nuclear, and the like to provide our electricity needs. As an example, most of our conventional electricity requirements for home and business use comes from turbines run on coal or other forms of fossil fuel, nuclear power generation plants, and hydroelectric plants, as well as other forms of renewable energy. Often times, home and business use of electrical power has been stable and widespread.

Most importantly, much if not all of the useful energy found on the Earth comes from our sun. Generally all common plant life on the Earth achieves life using photosynthesis processes from sun light. Fossil fuels such as oil were also developed from biological materials derived from energy associated with the sun. For human beings including “sun worshipers,” sunlight has been essential. For life on the planet Earth, the sun has been our most important energy source and fuel for modern day solar energy.

Solar energy possesses many characteristics that are very desirable! Solar energy is renewable, clean, abundant, and often widespread. Certain technologies developed often capture solar energy, concentrate it, store it, and convert it into other useful forms of energy.

Solar panels have been developed to convert sunlight into energy. As merely an example, solar thermal panels often convert electromagnetic radiation from the sun into thermal energy for heating homes, running certain industrial processes, or driving high grade turbines to generate electricity. As another example, solar photovoltaic panels convert sunlight directly into electricity for a variety of applications. Solar panels are generally composed of an array of solar cells, which are interconnected to each other. The cells are often arranged in series and/or parallel groups of cells in series. Accordingly, solar panels have great potential to benefit our nation, security, and human users. They can even diversify our energy requirements and reduce the world's dependence on oil and other potentially detrimental sources of energy.

Although solar panels have been used successful for certain applications, there are still certain limitations. Solar cells are often costly. Depending upon the geographic region, there are often financial subsidies from governmental entities for purchasing solar panels, which often cannot compete with the direct purchase of electricity from public power companies. Additionally, the panels are often composed of silicon bearing wafer materials. Such wafer materials are often costly and difficult to manufacture efficiently on a large scale. Availability of solar panels is also somewhat scarce. That is, solar panels are often difficult to find and purchase from limited sources of photovoltaic silicon bearing materials. These and other limitations are described throughout the present specification, and may be described in more detail below.

From the above, it is seen that techniques for improving solar devices is highly desirable.

### BRIEF SUMMARY OF THE INVENTION

According to the present invention, techniques related to solar energy are provided. In particular, the present invention provides a method and resulting device fabricated from a plurality of photovoltaic regions provided within one or more substrate members. More particularly, the present invention provides a method and resulting device for manufacturing the photovoltaic regions within the substrate member, which is coupled to a plurality of concentrating elements, using a coupling technique between the photovoltaic regions and respective concentrating elements. Merely by way of example, the invention has been applied to solar panels, commonly termed modules, but it would be recognized that the invention has a much broader range of applicability.

In a specific embodiment, the present invention provides a method for fabricating a solar cell free and separate from a solar panel. The method includes providing a lead frame member comprising at least one photovoltaic strip thereon. In a preferred embodiment, the photovoltaic strip has a surface region and a back side region, which is provided on the lead frame member. The method includes providing an optical elastomer material having a first thickness. The method includes providing a second substrate member comprising at least one optical concentrating element thereon. In a specific embodiment, the optical concentrating element has a first side and a second side. The method includes coupling the optical concentrating element such that the optical elastomer material is in between the surface region of the photovoltaic strip and the second side of the optical concentrating element to form a first interface within a vicinity of the surface region and the thickness of the optical elastomer material and a second interface within a vicinity of the second side and the optical elastomer material. The method maintains a spacing between the second side of the optical concentrating element and the surface region of the photovoltaic strip using a plurality of particles having a predetermined dimension spatially disposed overlying the surface region of the photovoltaic strip and within a second thickness of the optical elastomer material. The method includes curing the optical elastomer material between the surface region and the second side. The method also includes providing the first interface substantially free from one or more gaps (e.g., air gaps and/or pockets, bubbles, vapor) and the second interface substantially free from one or more gaps to form a substantially continuous optical interface from the first side of the optical concentrating element, through the first interface, and through the second interface to the photovoltaic strip.

In an alternative specific embodiment, the present invention provides a solar cell device. The device has a housing member, e.g., molded plate, transfer molded material, injection molded material, dam bar molded material, assembled plate. The device also has a lead frame member coupled to the housing member. In a preferred embodiment, the lead frame member has at least one photovoltaic strip thereon, which has a surface region and a back side region. The device has an optical elastomer material having a first thickness overlying the surface region of the photovoltaic surface. The device has a second substrate member comprising at least one optical concentrating element thereon. The optical concentrating element has a first side and a second side. The device has a first interface within a vicinity of the surface region and the first thickness of the optical elastomer material and a second interface within a vicinity of the second side and the optical elastomer material. In a specific embodiment, the optical concentrating element is coupled to the surface region of the photovoltaic strip such that the optical elastomer material is in between the surface region of the photovoltaic strip and the second side of the optical concentrating element. In a specific embodiment, the device has a spacing comprising essentially the optical elastomer material between the second side of the optical concentrating element and the surface region of the photovoltaic strip. The device has a plurality of particles having a predetermined dimension (e.g., non-compressible and substantially non-deformable particles) spatially disposed overlying the surface region of the photovoltaic strip and within a second thickness of the optical elastomer material to define the spacing between the surface region and the second side of the optical concentrating element. In a specific embodiment, the first interface is substantially free from one or more gaps (e.g., air gaps and/or pockets) and the second interface substantially free from one or more gaps to form a substantially continuous optical interface from the first side of the optical concentrating element, through the first interface, and through the second interface to the photovoltaic strip.

Many benefits are achieved by way of the present invention over conventional techniques. For example, the present technique provides an easy to use process that relies upon conventional technology such as silicon materials, although other materials can also be used. Additionally, the method provides a process that is compatible with conventional process technology without substantial modifications to conventional equipment and processes. Preferably, the invention provides for an improved solar cell, which is less costly and easy to handle. Such solar cell uses a plurality of photovoltaic regions, which are coupled to concentrating elements according to a preferred embodiment. In a preferred embodiment, the invention provides a method and completed solar cell structure using a plurality of photovoltaic strips free and clear from a module or panel assembly, which are provided during a later assembly process. Also in a preferred embodiment, one or more of the solar cells have less silicon per area (e.g., 80% or less, 50% or less) than conventional solar cells. In preferred embodiments, the present method and cell structures are also light weight and not detrimental to building structures and the like. That is, the weight is about the same or slightly more than conventional solar cells at a module level according to a specific embodiment. In a preferred embodiment, the present solar cell using the plurality of photovoltaic strips can be used as a “drop in” replacement of conventional solar cell structures. As a drop in replacement, the present solar cell can be used with conventional solar cell technologies for efficient implementation according to a preferred embodiment. In a preferred embodiment, the present invention provides a resulting structure that is reliable and can withstand environmental conditions overtime. Depending upon the embodiment, one or more of these benefits may be achieved. These and other benefits will be described in more detail throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1 is a simplified diagram illustrating an expanded view of a solar cell structure according to an embodiment of the present invention;

FIG. 2 is a simplified top-view diagram of a solar cell according to an embodiment of the present invention;

FIG. 3 is a detailed cross-sectional view diagram of a photovoltaic region coupled to a concentrating element of a solar cell according to an embodiment of the present invention;

FIG. 4 is a detailed alternative cross-sectional view diagram of a photovoltaic region coupled to a concentrating element of a solar cell according to an embodiment of the present invention;

FIG. 5 is a detailed cross-sectional view diagram of a photovoltaic region coupled to a concentrating element of a solar cell according to an embodiment of the present invention; and

FIG. 5A is a larger detailed cross-sectional view diagram of the photovoltaic region coupled to the concentrating element of the solar cell of FIG. 5 according to an embodiment of the present invention.

### DETAILED DESCRIPTION OF THE INVENTION

According to the present invention, techniques related to solar energy are provided. In particular, the present invention provides a method and resulting device fabricated from a plurality of photovoltaic regions provided within one or more substrate members. More particularly, the present invention provides a method and resulting device for manufacturing the photovoltaic regions within the substrate member, which is coupled to a plurality of concentrating elements. Merely by way of example, the invention has been applied to solar panels, commonly termed modules, but it would be recognized that the invention has a much broader range of applicability.

A method for fabricating a solar cell structure according to an embodiment of the present invention may be outlined as follows:

1. Provide a lead frame member comprising at least one photovoltaic strip thereon;

2. Provide an optical elastomer material having a first thickness;

3. Provide a second substrate member comprising at least one optical concentrating element thereon;

4. Couple the optical concentrating element such that the optical elastomer material is in between the surface region of the photovoltaic strip and the second side of the optical concentrating element;

5. Form a first interface within a vicinity of the surface region and the thickness of the optical elastomer material;

6. Form a second interface within a vicinity of the second side and the optical elastomer material;

7. Maintain a spacing between the second side of the optical concentrating element and the surface region of the photovoltaic strip using a plurality of particles having a predetermined dimension spatially disposed overlying the surface region of the photovoltaic strip and within a second thickness of the optical elastomer material;

8. Cure the optical elastomer material between the surface region and the second side;

9. Provide the first interface substantially free from one or more gaps (e.g., air gaps and/or pockets, bubbles, vapor) and the second interface substantially free from one or more gaps to form a substantially continuous optical interface from the first side of the optical concentrating element, through the first interface, and through the second interface to the photovoltaic strip; and

10. Perform other steps, as desired.

The above sequence of steps provides a method according to an embodiment of the present invention. As shown, the method uses a combination of steps including a way of forming a solar cell for a solar panel, which has a plurality of solar cells. Other alternatives can also be provided where steps are added, one or more steps are removed, or one or more steps are provided in a different sequence without departing from the scope of the claims herein. Further details of the present method and resulting structures can be found throughout the present specification and more particularly below.

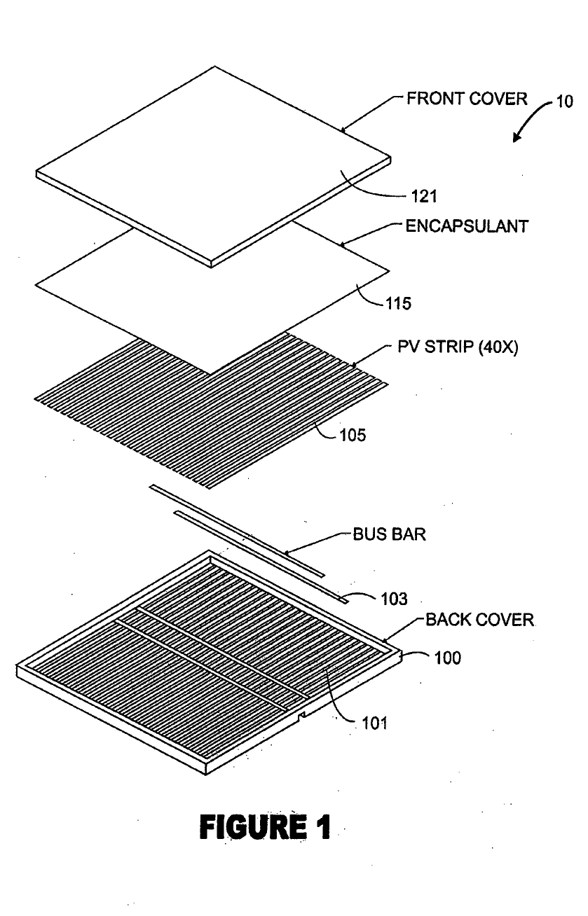

Referring now to FIG. 1, an expanded view 10 of a solar cell structure according to an embodiment of the present invention is illustrated. This diagram is merely an example, which should not unduly limit the scope of the claims herein. One of ordinary skill in the art would recognize many variations, modifications, and alternatives. As shown is an expanded view of the present solar cell device structure, which includes various elements. The device has a back cover member 101, which includes a surface area and a back area. The back cover member also has a plurality of sites, which are spatially disposed, for electrical members, such as bus bars, and a plurality of photovoltaic regions. In a specific embodiment, the bus bars can be provided on a lead frame structure, which will be described in more detail throughout the present specification and more particularly below. Of course, there can be other variations, modifications, and alternatives.

In a preferred embodiment, the device has a plurality of photovoltaic strips 105, each of which is disposed overlying the surface area of the back cover member. In a preferred embodiment, the plurality of photovoltaic strips correspond to a cumulative area occupying a total photovoltaic spatial region, which is active and converts sunlight into electrical energy. Of course, there can be other variations, modifications, and alternatives.

An encapsulating material 115 is overlying a portion of the back cover member. That is, an encapsulating material forms overlying the plurality of strips, and exposed regions of the back cover, and electrical members. In a preferred embodiment, the encapsulating material can be a single layer, multiple layers, or portions of layers, depending upon the application. Of course, there can be other variations, modifications, and alternatives.

In a specific embodiment, a front cover member 121 is coupled to the encapsulating material. That is, the front cover member is formed overlying the encapsulant to form a multilayered structure including at least the back cover, bus bars, plurality of photovoltaic strips, encapsulant, and front cover. In a preferred embodiment, the front cover includes one or more concentrating elements, which concentrate (e.g., intensify per unit area) sunlight onto the plurality of photovoltaic strips. That is, each of the concentrating elements can be associated respectively with each of or at least one of the photovoltaic strips.

Upon assembly of the back cover, bus bars, photovoltaic strips, encapsulant, and front cover, an interface region is provided along at least a peripheral region of the back cover member and the front cover member. The interface region may also be provided surrounding each of the strips or certain groups of the strips depending upon the embodiment. The device has a sealed region and is formed on at least the interface region to form an individual solar cell from the back cover member and the front cover member. The sealed region maintains the active regions, including photovoltaic strips, in a controlled environment free from external effects, such as weather, mechanical handling, environmental conditions, and other influences that may degrade the quality of the solar cell. Additionally, the sealed region and/or sealed member (e.g., two substrates) protect certain optical characteristics associated with the solar cell and also protects and maintains any of the electrical conductive members, such as bus bars, interconnects, and the like. Details of sealing the assembly together can be found in U.S. patent application Ser. No. 11/402,490 [Attorney Docket No. 025902-000510US] and U.S. Provisional Patent Application Ser. No. 60/688,077 [Attorney Docket Number 025902-000200US)], commonly assigned, and hereby incorporated by reference for all purposes. Of course, there can be other benefits achieved using the sealed member structure according to other embodiments.

In a preferred embodiment, the total photovoltaic spatial region occupies a smaller spatial region than the surface area of the back cover. That is, the total photovoltaic spatial region uses less silicon than conventional solar cells for a given solar cell size. In a preferred embodiment, the total photovoltaic spatial region occupies about 80% and less of the surface area of the back cover for the individual solar cell. Depending upon the embodiment, the photovoltaic spatial region may also occupy about 70% and less or 60% and less or preferably 50% and less of the surface area of the back cover or given area of a solar cell. Of course, there can be other percentages that have not been expressly recited according to other embodiments. Here, the terms “back cover member” and “front cover member” are provided for illustrative purposes, and not intended to limit the scope of the claims to a particular configuration relative to a spatial orientation according to a specific embodiment. Further details of various elements in the solar cell can be found throughout the present specification and more particularly below. More particularly, certain details on coupling each of the photovoltaic regions to the concentrating elements can be found throughout the present specification and more particularly below.

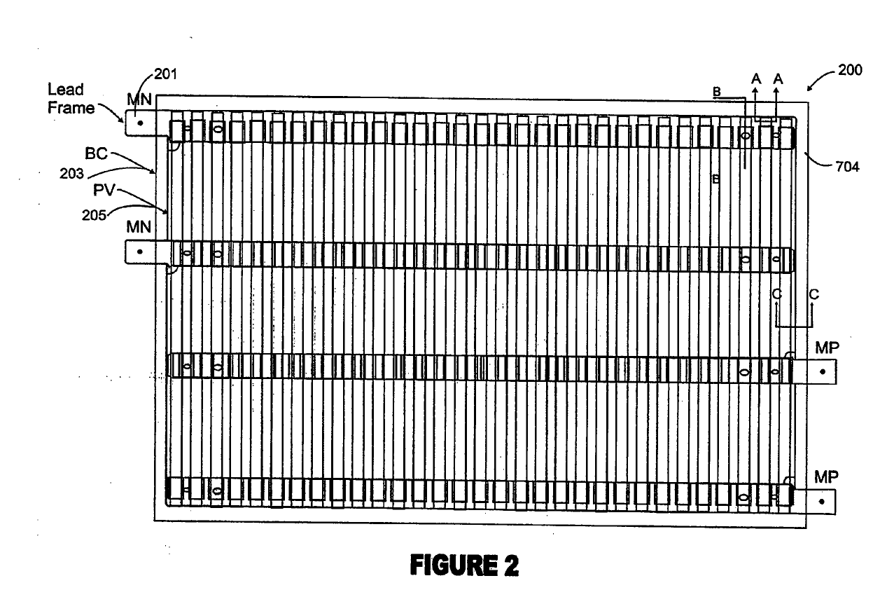

FIG. 2 is a simplified top-view diagram 200 of a solar cell according to an embodiment of the present invention. This diagram is merely an example, which should not unduly limit the scope of the claims herein. One of ordinary skill in the art would recognize many variations, modifications, and alternatives. In an alternative specific embodiment, the present invention provides a solar cell device. The device has a housing member, which is a back cover member 203. The device also has a lead frame member 201 coupled to the housing member. In a specific embodiment, the lead frame member can be selected from a copper member and/or an Alloy 42 member. Of course, there can be other variations, modifications, and alternatives.

In a preferred embodiment, the lead frame member has at least one photovoltaic strip 205 thereon, which has a surface region and a back side region. In a specific embodiment, each of the photovoltaic strips is made of a silicon bearing material, which includes a photo energy conversion device therein. That is, each of the strips is made of single crystal and/or poly crystalline silicon that have suitable characteristics to cause it to convert applied sunlight or electromagnetic radiation into electric current energy according to a specific embodiment. An example of such a strip is called the Sliver Cell® product manufactured by Origin Energy of Australia, but can be others. In other examples, the strips or regions of photovoltaic material can be made of other suitable materials such as other semiconductor materials, including semiconductor elements listed in the Periodic Table of Elements, polymeric materials that have photovoltaic properties, or any combination of these, and the like. In a specific embodiment, the photovoltaic region is provided on the lead frame using a conductive epoxy paste and/or solder adhesive, including paste and/or other bonding techniques. Of course, there can be other variations, modifications, and alternatives.

In a specific embodiment, the device has an optical elastomer material having a first thickness overlying the surface region of the photovoltaic surface. The elastomer material is an optical elastomer material, which begins as a liquid and cures to form a solid material. The elastomer material has suitable thermal and optical characteristics. That is, a refractive index of the elastomer material is substantially matched to an overlying concentrating element according to a specific embodiment. In a specific embodiment, the encapsulant material adapts for a first coefficient of thermal expansion of the plurality of photovoltaic strips on the lead frame member and a second coefficient of thermal expansion associated with the concentrating element. In a specific embodiment, the encapsulant material facilitates transfer of one of more photons between one of the concentrating elements and one of the plurality of photovoltaic strips. The encapsulant material can act as a barrier material, an electrical isolating structure, a glue layer, and other desirable features. The encapsulating material can also be a tape and/or film according to a specific embodiment. Depending upon the embodiment, the encapsulant material can be cured using a thermal, ultraviolet, and/or other process according to a specific embodiment. As merely an example, the encapsulating material is silicone gel, epoxy, polyurethane based adhesive, 2-sided acrylic based adhesive film, but can be others. Of course, there can be other variations, modifications, and alternatives. In a specific embodiment, the device has a second substrate member comprising at least one optical concentrating element thereon. Further details of the concentrating element and other features can be found in the figures described below.

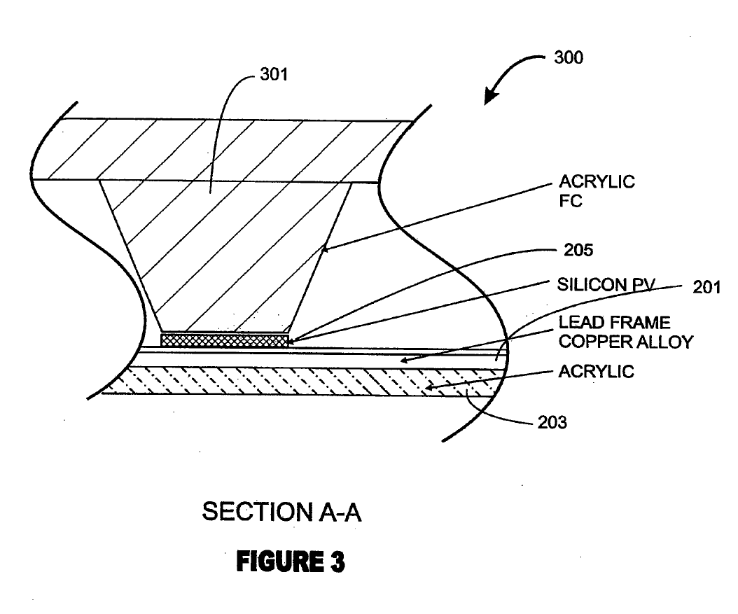

FIG. 3 is a detailed cross-sectional view diagram 300 of a photovoltaic region coupled to a concentrating element of a solar cell according to an embodiment of the present invention. This diagram is merely an example, which should not unduly limit the scope of the claims herein. One of ordinary skill in the art would recognize many variations, modifications, and alternatives. As shown, FIG. 3 is a cross section of “SECTION A-A” illustrated in FIG. 2. As shown, the device has an optical concentrating element 301, which has a first side and a second side. The device also has other element including the back cover, photovoltaic region, lead frame, and others. Specific details of other views of the device are provided throughout the present specification and more particularly below.

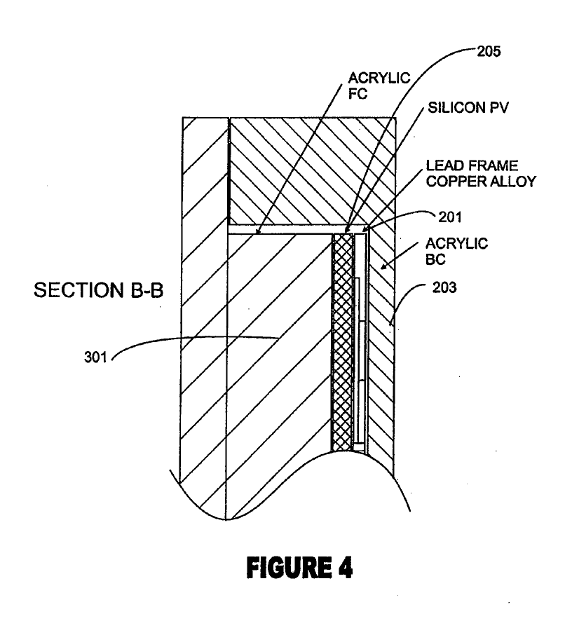

FIG. 4 is a detailed alternative cross-sectional view diagram 400 of a photovoltaic region coupled to a concentrating element of a solar cell according to an embodiment of the present invention. This diagram is merely an example, which should not unduly limit the scope of the claims herein. One of ordinary skill in the art would recognize many variations, modifications, and alternatives. As shown, FIG. 4 is a cross section of “SECTION B-B” illustrated in FIG. 2. As shown, the device has an optical concentrating element 301, which has a first side and a second side. The device also has other element including the back cover, photovoltaic region, lead frame, and others. Specific details of other views of the device are provided throughout the present specification and more particularly below.

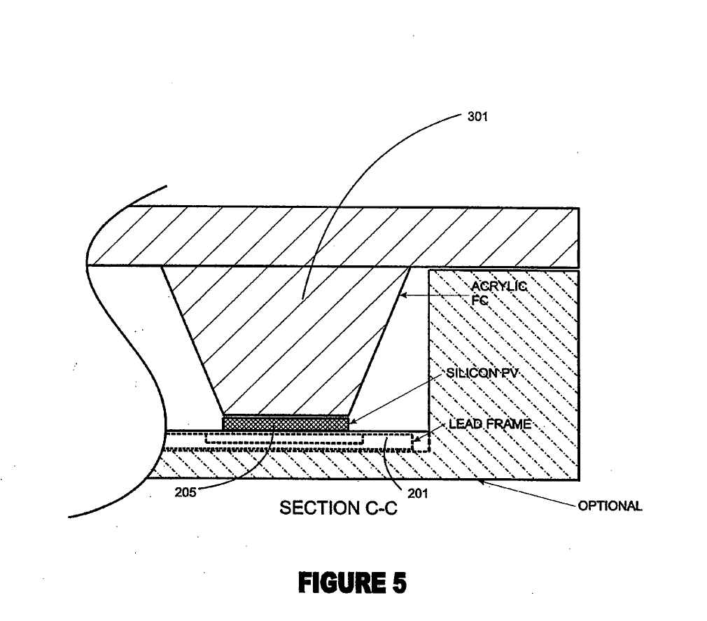

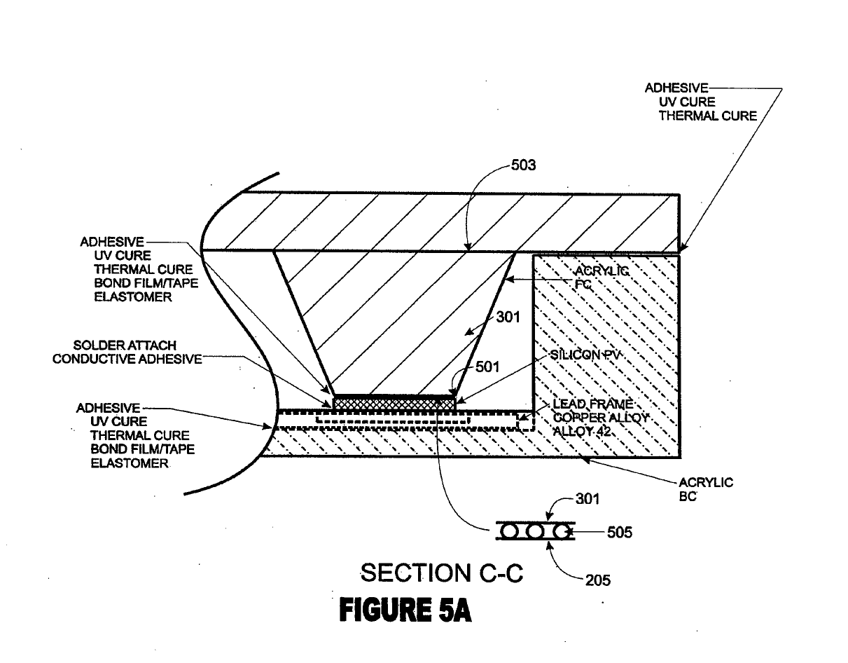

FIG. 5 is a detailed cross-sectional view diagram of a photovoltaic region coupled to a concentrating element of a solar cell according to an embodiment of the present invention. This diagram is merely an example, which should not unduly limit the scope of the claims herein. One of ordinary skill in the art would recognize many variations, modifications, and alternatives. As shown, FIG. 5 is a cross section of “SECTION C-C” illustrated in FIG. 2. More specifically, FIG. 5A is a larger detailed cross-sectional view diagram of the photovoltaic region coupled to the concentrating element of the solar cell of FIG. 5 according to an embodiment of the present invention. This diagram is merely an example, which should not unduly limit the scope of the claims herein. One of ordinary skill in the art would recognize many variations, modifications, and alternatives. As shown, the device has an optical concentrating element 301, which has a first side 503 and a second side 501. The device also has other element including the back cover, photovoltaic region, lead frame, and others.

In a specific embodiment, the device has a first interface within a vicinity of the surface region and the first thickness of the optical elastomer material. The device also has a second interface within a vicinity of the second side and the optical elastomer material. In a specific embodiment, the optical concentrating element 301 is coupled to the surface region of the photovoltaic strip 205 such that the optical elastomer material is in between the surface region of the photovoltaic strip and the second side of the optical concentrating element. In a specific embodiment, the device has a spacing comprising essentially the optical elastomer material between the second side of the optical concentrating element and the surface region of the photovoltaic strip. The device has a plurality of particles 505 having a predetermined dimension (e.g., non-compressible and substantially non-deformable particles, spherical glass particles, which are substantially transparent) spatially disposed overlying the surface region of the photovoltaic strip and within a second thickness of the optical elastomer material to define the spacing between the surface region and the second side of the optical concentrating element. As merely an example, the particles are glass beads, but can be others. In a specific embodiment, the second thickness is the same as the first thickness, although they can differ in other embodiments. In a specific embodiment, the first interface is substantially free from one or more gaps (e.g., air gaps and/or pockets) and the second interface substantially free from one or more gaps to form a substantially continuous optical interface from the first side of the optical concentrating element, through the first interface, and through the second interface to the photovoltaic strip. Of course, there can be other variations, modifications, and alternatives.

It is also understood that the examples and embodiments described herein are for illustrative purposes only and that various modifications or changes in light thereof will be suggested to persons skilled in the art and are to be included within the spirit and purview of this application and scope of the appended claims.

1. (canceled)

2. (canceled)

3. (canceled)

4. A solar cell device comprising:
a housing member;
a first substrate member comprising at least a lead frame member, the lead frame member being coupled to the housing member, the lead frame member comprising at least one photovoltaic strip thereon, the photovoltaic strip having a surface region and a back side region, the backside region being provided on the lead frame member;
an optical elastomer material having a first thickness overlying the surface region of the photovoltaic surface strip;
a second substrate member comprising at least one optical concentrating element thereon, the optical concentrating element comprising a first side and a second side;
a first interface within a vicinity of the surface region and the first thickness of the optical elastomer material and a second interface within a vicinity of the second side and the optical elastomer material, the optical concentrating element coupling the surface region of the photovoltaic strip such that the optical elastomer material is in between the surface region of the photovoltaic strip and the second side of the optical concentrating element;
a spacing comprising essentially the optical elastomer material between the second side of the optical concentrating element and the surface region of the photovoltaic strip;
a plurality of particles having a predetermined dimension spatially disposed overlying the surface region of the photovoltaic strip and within a second thickness of the optical elastomer material to define the spacing between the surface region and the second side of the optical concentrating element;
whereupon the first interface is substantially free from one or more gaps and the second interface substantially free from one or more gaps to form a substantially continuous optical interface from the first side of the optical concentrating element, through the first interface, and through the second interface to the photovoltaic strip.

5. The device of claim 4 wherein the optical elastomer material is a liquid.

6. The device of claim 4 wherein the curing comprises an ultra-violet cure.

7. The device of claim 4 wherein the curing comprises a thermal treatment.

8. The device of claim 4 wherein the optical elastomer material comprises a film of material.

9. The device of claim 4 wherein the optical elastomer material comprises a tape material.

10. The device of claim 4 wherein the photovoltaic strip is bonded to the first substrate using a solder material.

11. The device of claim 4 wherein the photovoltaic strip is bonded to the first substrate using a solder paste material.

12. The device of claim 4 wherein the concentrating element comprises a thickness of material between the first side and the second side.

13. The device of claim 4 wherein the photovoltaic strip is one of a plurality of photovoltaic strips.

14. The method of claim 13 wherein each of the photovoltaic strips comprises a silicon bearing material.

15. The device of claim 4 wherein the first substrate member comprises a copper material or an Alloy 42 material.

16. The device of claim 4 wherein the first interface is substantially free from air bubbles within the one or more gaps.

17. The device of claim 4 wherein the plurality of particles comprises a plurality of spherical glass beads.

18. The device of claim 4 wherein the plurality of particles are embedded in the optical elastomer material.

19. The device of claim 4 further comprising providing a backside housing on the lead frame member.

20. A solar cell device comprising:
a housing member;
a first substrate member comprising at least a lead frame member, the lead frame member being coupled to the housing member, the lead frame member comprising at least one photovoltaic strip thereon, the photovoltaic strip having a surface region and a back side region, the backside region being provided on the lead frame member, the photovoltaic strip being one of a plurality of photovoltaic strips, each of the photovoltaic strips comprising a silicon bearing material;
an optical elastomer material having a first thickness overlying the surface region of the photovoltaic strip, the optical elastomer material comprising a film of liquid material, the optical elastomer material being cured using a thermal treatment process;
a second substrate member comprising at least one optical concentrating element thereon, the optical concentrating element comprising a first side and a second side;
a first interface within a vicinity of the surface region and the first thickness of the optical elastomer material and a second interface within a vicinity of the second side and the optical elastomer material, the optical concentrating element coupling the surface region of the photovoltaic strip such that the optical elastomer material is in between the surface region of the photovoltaic strip and the second side of the optical concentrating element;
a spacing comprising essentially the optical elastomer material between the second side of the optical concentrating element and the surface region of the photovoltaic strip;
a plurality of particles having a predetermined dimension spatially disposed overlying the surface region of the photovoltaic strip and within a second thickness of the optical elastomer material to define the spacing between the surface region and the second side of the optical concentrating element, the plurality of particles comprising a plurality of spherical glass beads, the plurality of particles being embedded in the optical elastomer material;
a backside housing on the lead frame member;
whereupon the first interface is substantially free from one or more gaps and the second interface substantially free from one or more gaps to form a substantially continuous optical interface from the first side of the optical concentrating element, through the first interface, and through the second interface to the photovoltaic strip.

21. (canceled)
